(19) United States
(12) Patent Application Publication
(10) Pub. No.: US 2015/0280657 A1
(43) Pub. Date: Oct. 1, 2015

(54) ADAPTIVE DIGITAL PRE-DISTORTION

(71) Applicant: QUALCOMM Incorporated, San Diego, CA (US)

(72) Inventors: Haojen Cheng, Santa Clara, CA (US); Hao Zhou, Sunnyvale, CA (US); Chiao-Cheng Huang, HsinChu City (TW)

(21) Appl. No.: 14/316,296

(22) Filed: Jun. 26, 2014

Related U.S. Application Data
(60) Provisional application No. 61/971,766, filed on Mar. 28, 2014.

(51) Int. Cl. H03F 1/32; H04B 1/04

(52) U.S. Cl. CPC H03F 1/3241; H04B 1/0475; H03F 2201/3215; H03F 2201/3233; H04B 2001/045; H04B 2001/0425

(57) ABSTRACT

Methods, systems, and devices are described for adaptive digital pre-distortion (DPD). A wireless device may identify a transmission parameter, such as data rate or transmission power, for a signal to be transmitted by a wireless modem. The wireless device may then select a power amplification response based on whether the transmission parameter exceeds a threshold. A non-linear power amplification response may be selected in cases when the data rate is low or the transmission power is high. A linear power amplification response may be selected when the data rate is high or the transmission power is low. The power amplification response may be achieved by digital distortion of the signal prior to power amplification, so selection of the response may involve adjusting a DPD compensation circuit. In some cases, the output for the non-linear response may be characterized by a Rapp model.

### CROSS REFERENCES

The present application for patent claims priority to U.S. Provisional Patent Application No. 61/971,766 by Cheng et al., entitled “ADAPTIVE DIGITAL PRE-DISTORTION” filed Mar. 28, 2014, assigned to the assignee hereof, and expressly incorporated by reference herein.

### BACKGROUND

The following relates generally to wireless communication, and more specifically to adaptive digital pre-distortion. Wireless communications systems are widely deployed to provide various types of communication content such as voice, video, packet data, messaging, broadcast, and so on. These systems may be multiple-access systems capable of supporting communication with multiple users by sharing the available system resources (e.g., time, frequency, and power).

A wireless communications network may include a number of network devices, such as access points (APs), that can support communication for a number of wireless stations (STAs). A wireless device, such as an access point or station, may communicate with another wireless device bi-directionally. For example, in a wireless local area network (WLAN), a station may communicate with an associated AP via downlink and uplink. The downlink (or forward link) refers to the communication link from the AP to the station, and the uplink (or reverse link) refers to the communication link from the station to the AP.

Wireless communications systems may be subject to regulatory masks that limit the amount of energy that may leak from transmit frequencies onto neighboring frequencies. Thus, the transmission may be subject to a spectral mask limit specifying an acceptable amount of spectral leakage. Transmission power may be limited to meet the limits of a spectral mask, which may limit the range and/or reliability of a transmitted wireless signal.

### SUMMARY

The described features generally relate to one or more improved systems, methods, and/or apparatuses for adaptive digital pre-distortion (DPD). A wireless device may identify a transmission parameter, such as data rate or transmission power, for a signal to be transmitted by a wireless modem. The wireless device may then select a power amplification response based on whether the transmission parameter exceeds a threshold. A non-linear power amplification response may be selected in cases when the data rate is low or the transmission power is high. A linear power amplification response may be selected when the data rate is high or the transmission power is low. The power amplification response may be achieved by digital distortion of the signal prior to power amplification, so selection of the response may involve adjusting a DPD compensation circuit. In some cases, the output for the non-linear response may be characterized by a Rapp model.

A method of adaptive digital pre-distortion is described, including identifying a transmission parameter for a signal to be transmitted by a wireless modem, wherein the transmission parameter is selected from the group consisting of: a transmission power and a data rate, and selecting, based at least in part on a transmission parameter of the signal, one from the group consisting of a first power amplification response or a second power amplification response for the wireless modem, wherein the second power amplification response is more linear than the first power amplification response.

An apparatus for adaptive digital pre-distortion is described, including means for identifying a transmission parameter for a signal to be transmitted by a wireless modem, wherein the transmission parameter is selected from the group consisting of: a transmission power and a data rate, and means for selecting, based at least in part on a transmission parameter of the signal, one from the group consisting of a first power amplification response and a second power amplification response for the wireless modem, wherein the second power amplification response is more linear than the first power amplification response.

An apparatus for adaptive DPD is also described, including an adaptive DPD circuit and a power amplifier. The adaptive DPD circuit may be configured to identify a transmission parameter for a signal to be transmitted by a wireless modem, wherein the transmission parameter is selected from the group consisting of a transmission power and a data rate, and select based at least in part on the transmission parameter of the signal, one from the group consisting of a first power amplification response or a second power amplification response for the wireless modem, wherein the second power amplification response is more linear than the first power amplification response.

A computer program product for adaptive digital pre-distortion is also described, the computer program product comprising a non-transitory computer-readable medium storing instructions executable by a processor to identify a transmission parameter for a signal to be transmitted by a wireless modem, and select based at least in part on a transmission parameter of the signal, one from the group consisting of a first power amplification response or a second power amplification response for the wireless modem, wherein the second power amplification response is more linear than the first power amplification response. The transmission parameter may be selected from the group consisting of: a transmission power and a data rate.

In some examples of the method, apparatuses, and/or computer program product described above, the transmission parameter may be a data rate that is compared to a threshold. For example, selecting one from the group consisting of the first power amplification response or the second power amplification response may include selecting the first power amplification response in response to a determination that the data rate is less than the threshold. Some examples comprise the selecting one from the group consisting of the first power amplification response or the second power amplification response may include selecting the second power amplification response in response to a determination that the data rate is greater than the threshold.

In some examples of the method, apparatuses, and/or computer program product described above, selecting one from the group consisting of the first power amplification response or the second power amplification response may include adjusting a DPD circuit of the wireless modem. In some examples, adjusting the DPD circuit of the wireless modem may include selecting a pre-distortion function based on the selected power amplification response.

In some examples of the method, apparatuses, and/or computer program product described above, the first power amplification response may be characterized by a non-linear Rapp function. In some examples, the second power amplification response may be characterized by a piecewise linear function.

In some examples of the method, apparatuses, and/or computer program product described above, the data rate may correspond to a modulation and coding scheme (MCS) index.

Further scope of the applicability of the described methods and apparatuses will become apparent from the following detailed description, claims, and drawings. The detailed description and specific examples are given by way of illustration only, since various changes and modifications within the scope of the description will become apparent to those skilled in the art.

### BRIEF DESCRIPTION OF THE DRAWINGS

A further understanding of the nature and advantages of the present invention may be realized by reference to the following drawings. In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 illustrates an example of a wireless communications system in accordance with various aspects;

FIG. 2 illustrates a diagram of a power amplification stage of a transmitter in accordance with various examples of the principles described herein;

FIG. 3 illustrates an example of a flowchart for adaptive digital pre-distortion in accordance with various examples of the principles described herein;

FIGS. 4A & 4B illustrate examples of power amplifications responses with adaptive digital pre-distortion in accordance with various examples of the principles described herein;

FIG. 5 shows a block diagram of a wireless device for adaptive digital pre-distortion in accordance with various examples of the principles described herein;

FIG. 6 shows a block diagram of a wireless device for adaptive digital pre-distortion in accordance with various examples of the principles described herein;

FIG. 7 shows a block diagram of a wireless device for adaptive digital pre-distortion in accordance with various examples of the principles described herein;

FIG. 8 illustrates a block diagram of a system for adaptive digital pre-distortion in accordance with various examples of the principles described herein;

FIG. 9 shows a flowchart illustrating a method for adaptive digital pre-distortion in accordance with various examples of the principles described herein;

FIG. 10 shows a flowchart illustrating a method for adaptive digital pre-distortion in accordance with various examples of the principles described herein; and

FIG. 11 shows a flowchart illustrating a method for adaptive digital pre-distortion in accordance with various examples of the principles described herein.

### DETAILED DESCRIPTION

The described features generally relate to one or more improved systems, methods, and/or apparatuses for adaptive digital pre-distortion (DPD) in a power amplification stage of a wireless modem of a wireless device. The wireless device may identify a transmission parameter, such as data rate or transmission power, for a signal to be transmitted by the wireless modem. The wireless device may then select a power amplification response based on whether the transmission parameter exceeds a threshold. A non-linear power amplification response may be selected in cases when the data rate is low or the transmission power is high. A linear power amplification response may be selected when the data rate is high or the transmission power is low. The power amplification response may be achieved by introducing digital distortion into the signal prior to power amplification, and selection of the response may involve adjusting a DPD compensation circuit. In some cases, the output for the non-linear response may be characterized by a Rapp model.

The techniques described herein may enable transmission of a signal that meets a spectral mask limit under a broad range of transmission parameters. For example, these techniques may enable a wireless device to utilize a higher transmission power when it is desirable to increase the range and/or reception reliability of a transmitted signal.

The following description provides examples, and is not limiting of the scope, applicability, or configuration set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to certain examples may be combined in other examples.

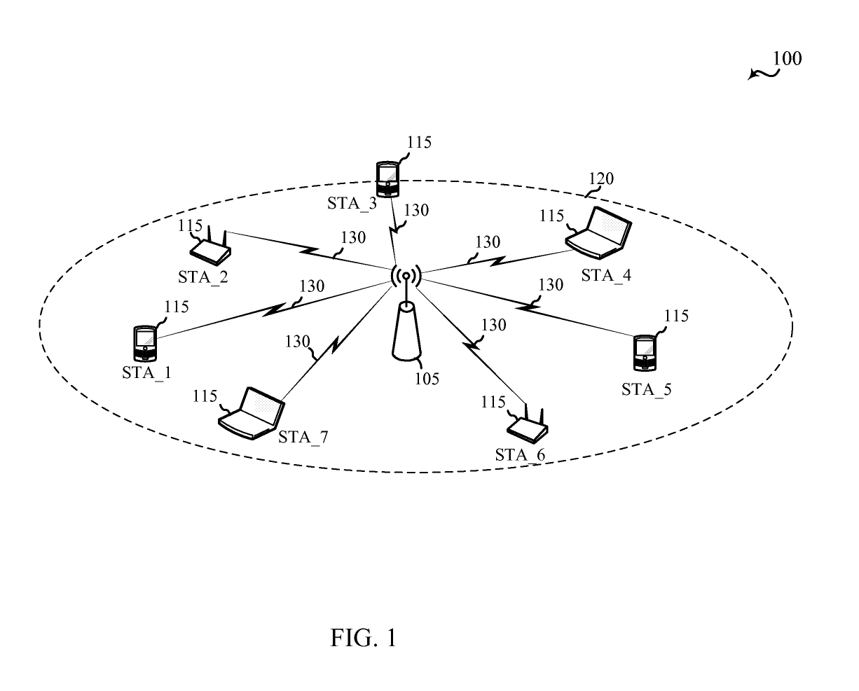

Referring first to FIG. 1, a WLAN 100 (also known as a Wi-Fi network) is shown that may be configured with adaptive DPD in accordance with various examples. The WLAN 100 includes an access point (AP) 105 and multiple associated stations 115. In this example, there are shown seven (7) wireless stations 115 (STAs), which are identified as STA_1, STA_2, STA_3, STA_4, STA_5, STA_6, and STA_7. The WLAN 100, however, may have more or fewer wireless stations 115 than those shown in FIG. 1 since the number shown is simply for illustrative purposes. The AP 105 and the associated wireless stations 115 may represent a basic service set (BSS). The various wireless stations 115 in the network are able to communicate with one another through the AP 105. Also shown is a coverage area 120 of the AP 105, which may represent a basic service area (BSA) of the WLAN 100. Although not shown in FIG. 1, an extended network base station associated with the WLAN 100 is typically connected to a wired or wireless distribution system (DS) that may allow multiple APs to be connected in an extended service set.

The AP 105 may be configured to communicate bi-directionally with each of the wireless stations 115 using transmissions 130. The transmissions 130 may include downlink transmissions (e.g., beacon frames) that are sent from the AP 105 to a wireless station 115 as well as uplink transmissions (e.g., acknowledgments or ACK frames) that are sent from a wireless station 115 to the AP 105. Typically, the AP 105 is configured to broadcast its downlink transmissions to the wireless stations 115 that are within the coverage area 120.

The wireless stations 115 are dispersed throughout the WLAN 100, and each wireless station 115 may be stationary or mobile. A wireless station 115 may be ground based or located on an airborne vehicle. A wireless station 115 may also be referred to as a user equipment (UE) a mobile device, a mobile station, a subscriber station, a mobile unit, a subscriber unit, a wireless unit, a remote unit, a UE, a wireless device, a wireless communications device, a remote device, a mobile subscriber station, an access terminal, a mobile terminal, a wireless terminal, a remote terminal, a handset, a user agent, a mobile client, a client, or some other suitable terminology. A wireless station 115 may be a two-way radio, a radio cellular phone, a personal digital assistant (PDA), a wireless modem, a handheld device, a tablet computer, a laptop computer, a cordless phone, a wireless local loop (WLL) station, a television, or any other wireless enabled device.

The AP and wireless stations 115 of the WLAN 100 may be subject to a spectral mask requirement that limits the amount of spectral leakage for transmissions 130. Thus, the AP 105 or wireless stations 115 may utilize adaptive DPD to reduce spectral leakage under certain conditions. For example, they may select a non-linear power amplification response when they have a low data rate or a high transmission power.

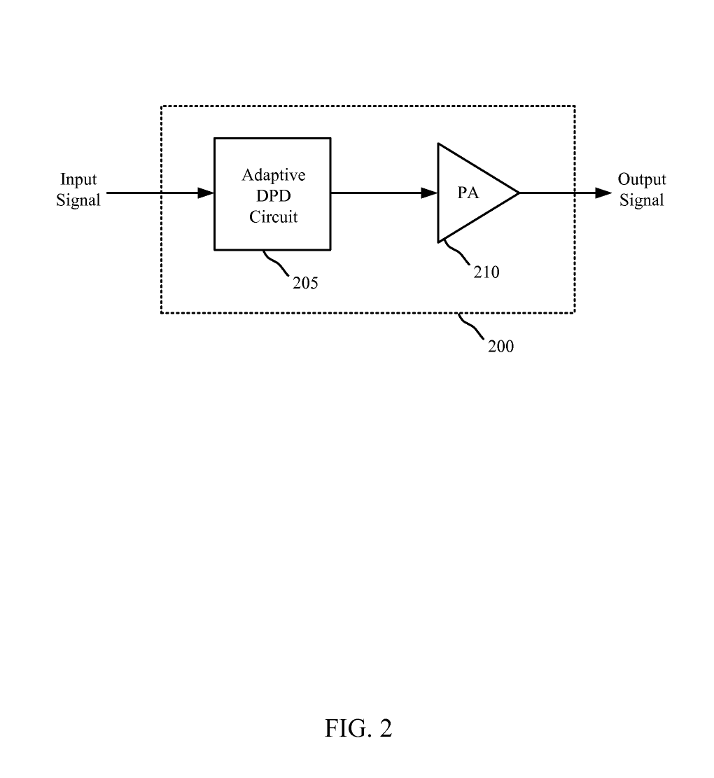

FIG. 2 illustrates a diagram of a power amplification stage 200 of a wireless device, such as one of the wireless stations 115 or the AP 105 of FIG. 1, in accordance with various examples. The diagram depicts an adaptive DPD circuit 205 that takes an input signal, applies compensating distortion, and then passes the distorted signal to a power amplifier 210.

The adaptive DPD circuit 205 may be a part of a signal processing or transmission chain in the wireless device. The adaptive DPD circuit 205 may inversely model the gain and phase characteristics of the power amplifier 210 so that after the input signal is amplified the resulting signal has the desired characteristics. In some cases, the adaptive DPD circuit 205 may be used to improve the linearity of the power amplifier (PA) 210. In other cases, the adaptive DPD circuit 205 may be configured to achieve a non-linear power amplification response in order to produce an output signal that meets a spectral mask limit.

The linearity of the power amplification response of the power amplification stage 200 may be dynamically adjusted by selectively configuring the type, amount, and degree of distortion added to the input signal by the adaptive DPD circuit 205. The linearity of the power amplification response may be adjusted to reflect different transmission scenarios. For example, it has been discovered that using a less linear power amplification response for lower bit-rate modulation and coding schemes (MCSs) may reduce out-of-band emissions, thereby allowing for a higher transmission power while maintaining compliance with spectral masks. For higher bit-rate MCSs and/or lower transmission power scenarios, a more linear power amplification response may be used to preserve signal integrity and improve demodulation and decoding at the receiver. Accordingly, the type and amount of distortion introduced to the input signal by the adaptive DPD circuit 205 may change based on the transmission parameters (e.g., data rate or transmission power) associated with the input signal.

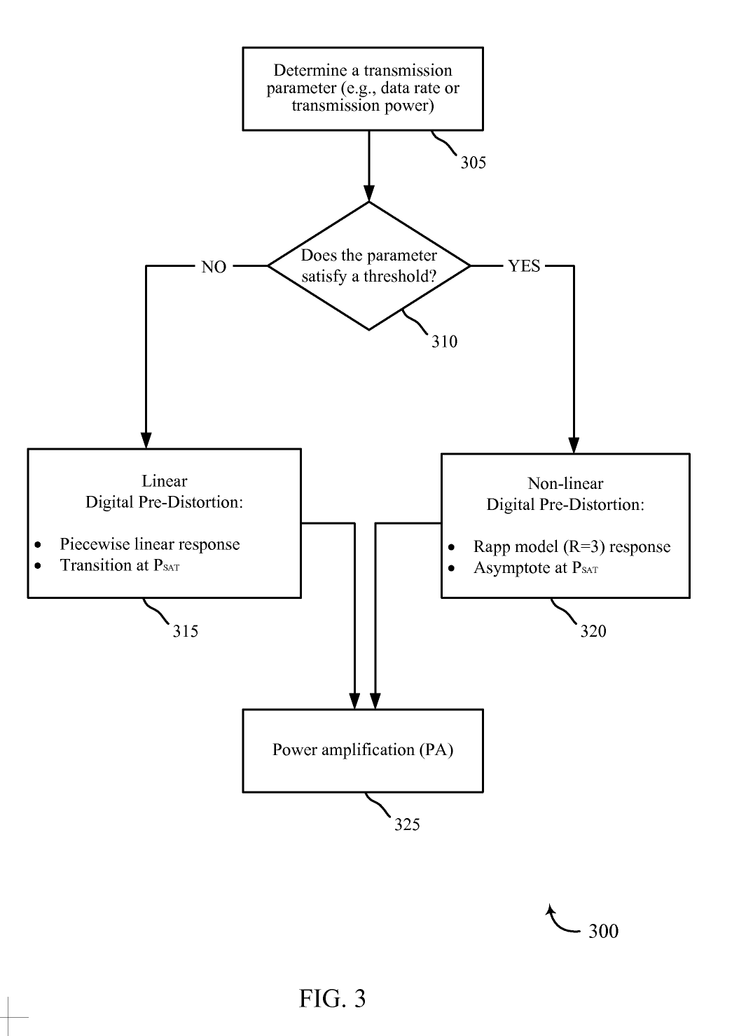

FIG. 3 illustrates an example of a flowchart 300 for adaptive digital pre-distortion in accordance with various examples. The operations of flowchart 300 may be performed by a wireless device, which may correspond to one of the wireless stations 115 or the access point 105 of FIG. 1 In some cases, the operations may additionally or alternatively be performed by the AP 105 described with reference to FIG. 1. At block 305, the wireless device may determine a transmission parameter such as a data rate or a transmission power for a wireless transmission. At block 310, the wireless device may determine whether the parameter meets a threshold limit. For example, the wireless device may determine whether a data rate is below a threshold or whether a transmission power is above a threshold.

At block 315, if the transmission parameter does not meet the threshold (e.g., the data rate is below a data rate threshold or the transmission power is greater than a power threshold), the wireless device 501 may select a DPD associated with a linear power amplification response. For example, the amplification response function (taking the pre-DPD signal as the input and the post amplification signal as the output) may be characterized by a piece-wise linear function with a maximum determined by a predetermined saturation power (P_{SAT}).

At block 320, if the transmission parameter meets the threshold (e.g., the data rate is at or above the data rate threshold or the transmission power is at or lower than the power threshold), the wireless device may select a DPD mode to achieve a non-linear power output.

For example, the wireless device 501 may select a power amplification response that is characterized by a Rapp model (e.g., with Rapp parameter R=3, as indicated in FIG. 3). The response may asymptotically approach P_{SAT}.

At block 325, after application of the linear or non-linear DPD, the signal may be amplified by a power amplification circuit and subsequently transmitted to another wireless device (not shown). Based on the adaptive selection of the DPD, the transmitted signal may meet a spectral mask limit, which may be specified by an industry determined standard.

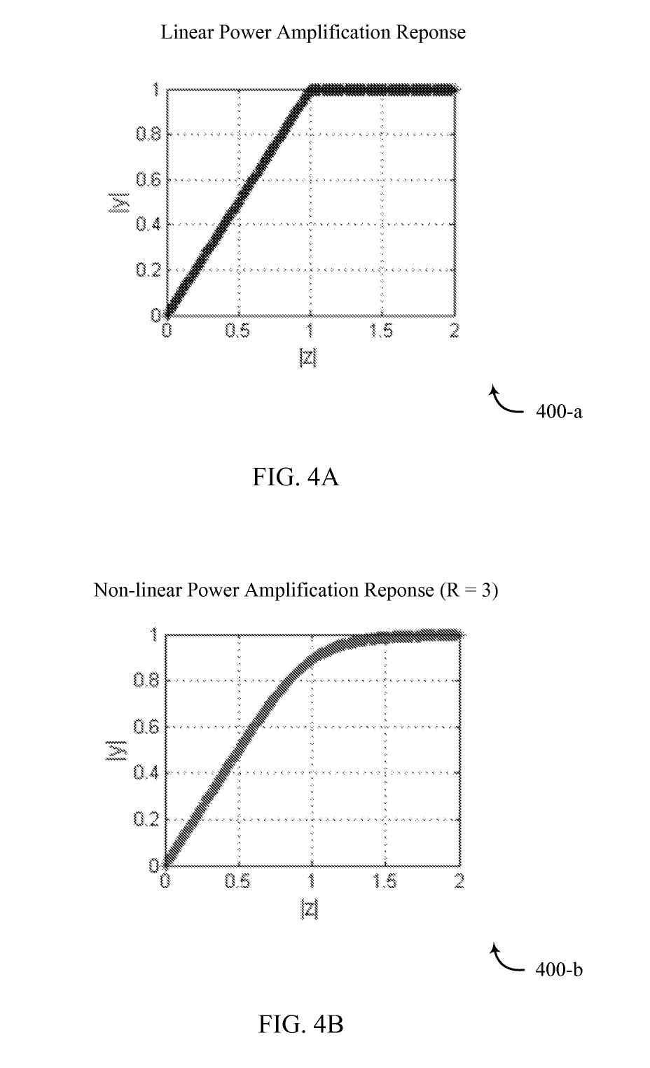

FIGS. 4A & 4B illustrate examples of power amplifications responses with adaptive digital pre-distortion in accordance with various examples. FIG. 4A illustrates a linear power amplification response function 400-a of a wireless device implementing adaptive DPD. The wireless device may be one of the wireless stations 115 or the access point 105 of FIG. 1.

The power amplification response function 400-a of FIG. 4A may be a piecewise linear function of the absolute value of the input signal power (depicted as |z|) on the horizontal axis, with an output (depicted as |y|) on the vertical axis. The function shown in FIG. 4A may be normalized so that P_{SAT} lies at 1 on the vertical axis. The linear function may be piecewise linear such that from input power 0 to 1, the response is directly proportional to the input. At or above input power |z|=1, the function may transition to a constant function (e.g., |y|=P_{SAT}) such that:

$$\vert y \vert = \{ \begin{matrix}\vert z \vert & from \vert z \vert = 0 to 1 \\ 1 & for \vert z \vert \geq 1\end{matrix} \qquad ( 1 )$$

FIG. 4B shows a non-linear power amplification response function of a wireless device implementing adaptive DPD. The wireless device may be one of the wireless stations 115 or the access point 105 shown in FIG. 1. The function may be a differentiable curve in the range |z|>0 normalized so that it has an asymptote (P_{SAT}) at |y|=1, such that.

$$\vert y \vert = \frac{\vert z \vert}{{( {( 1 + \vert z \vert )}^{2 R} )}^{\frac{1}{2 R}}} for \vert z \vert > 0 \qquad ( 2 )$$

In some cases the non-linear power amplification response may be characterized by a Rapp model with parameter R=3. In other cases the parameter may be within a range of parameters, e.g. R=2 to R=8.

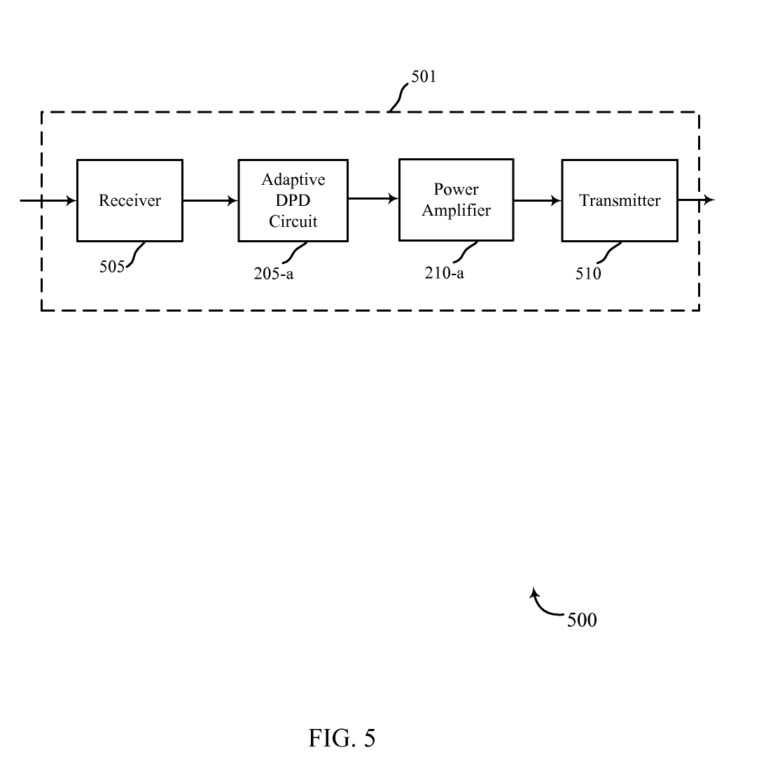

FIG. 5 shows a block diagram 500 of a wireless device 501 for adaptive digital pre-distortion in accordance with various examples. The wireless device 501 may be an example of one or more aspects of the wireless stations 115 or AP 105 shown in FIG. 1 or the wireless devices described with reference to FIGS. 2-5. The wireless device 501 may include a receiver 505, an adaptive DPD circuit 205-a, a power amplifier 210-a and/or a transmitter 510. The wireless device 501 may also include a processor (not shown). Each of these components may be in communication with each other.

The components of the wireless device 501 may, individually or collectively, be implemented with one or more application-specific integrated circuits (ASICs) adapted to perform some or all of the applicable functions in hardware. Alternatively, the functions may be performed by one or more other processing units (or cores), on one or more integrated circuits. In other examples, other types of integrated circuits may be used (e.g., Structured/Platform ASICs, Field Programmable Gate Arrays (FPGAs), and other Semi-Custom ICs), which may be programmed in any manner known in the art. The functions of each unit may also be implemented, in whole or in part, with instructions embodied in a memory, formatted to be executed by one or more general or application-specific processors.

The receiver 505 may receive information such as packets, user data, and/or control information associated with various information channels (e.g., control channels, data channels, etc.). The receiver 505 may receive the information by detecting radiated electromagnetic energy on one or more antennas, then demodulating and decoding the energy into the information. The information may be passed on to other components of the wireless device 501.

The adaptive DPD circuit 205-a may be configured to identify a transmission parameter for a signal to be transmitted by a wireless modem. The adaptive DPD circuit 205-a may also be configured to select based at least in part on a transmission parameter of the signal, one from the group consisting of a first power amplification response or a second power amplification response for the wireless modem, wherein the second power amplification response is more linear than the first power amplification response.

The power amplifier 210-a may take a signal processed by the adaptive DPD circuit 205-a and amplify the power of the signal. The amplification response of the adaptive DPD circuit 205-a and the power amplifier 210-a may be linear or non-linear with respect to the input signal based on the mode selected by the adaptive DPD circuit 205-a.

The transmitter 510 may transmit the one or more signals received from other components of the wireless device 501, such as a signal amplified by the power amplifier. In some examples, the transmitter 510 may be collocated with the receiver 505 in a transceiver. The transmitter 510 may include a single antenna or a plurality of antennas.

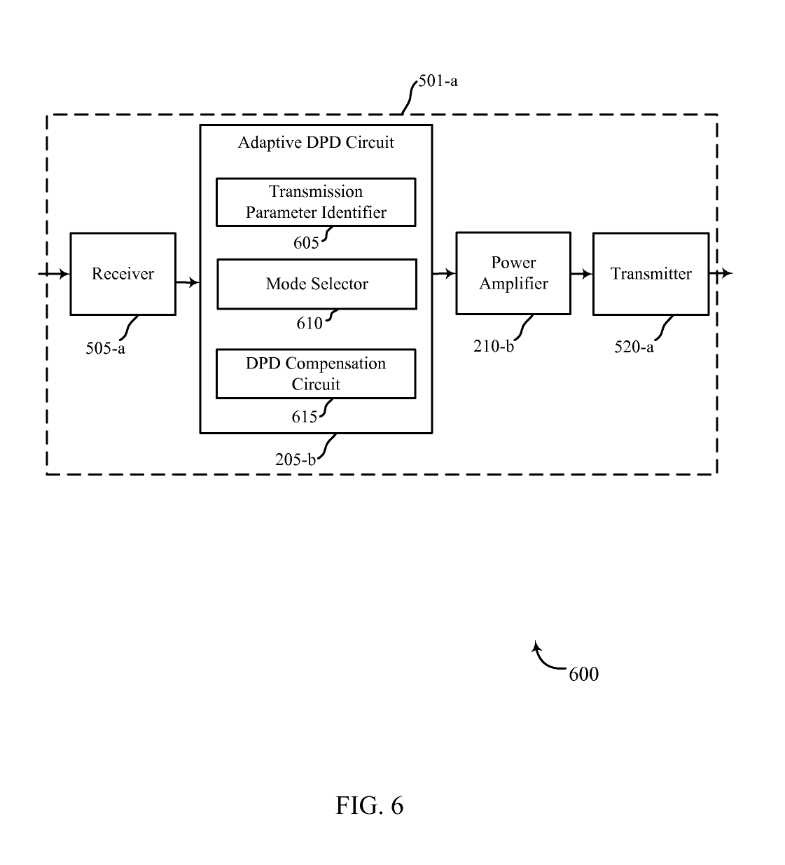

FIG. 6 shows a block diagram 600 of a wireless device 501-a for adaptive digital pre-distortion in accordance with various examples. The wireless device 501-a may be an example of one or more aspects of the wireless stations 115 or access point 105 shown in FIG. 1, the wireless devices described with reference to FIGS. 2-4, or the wireless device 501 shown and described in FIG. 5. The wireless device 501-a may include a receiver 505-a, an adaptive DPD circuit 205-b, a power amplifier 210-b and/or a transmitter 510-a. The wireless device 501-a may also include a processor. Each of these components may be in communication with each other. The adaptive DPD circuit 205-b may also include a transmission parameter identifier 605, a mode selector 610, and a DPD compensation circuit 615.

The components of the wireless device 501-a may, individually or collectively, be implemented with one or more application-specific integrated circuits (ASICs) adapted to perform some or all of the applicable functions in hardware. Alternatively, the functions may be performed by one or more other processing units (or cores), on one or more integrated circuits. In other examples, other types of integrated circuits may be used (e.g., Structured/Platform ASICs, Field Programmable Gate Arrays (FPGAs), and other Semi-Custom ICs), which may be programmed in any manner known in the art. The functions of each unit may also be implemented, in whole or in part, with instructions embodied in a memory, formatted to be executed by one or more general or application-specific processors.

The receiver 505-a may receive information which may be passed on to the n-a, and to other components of the wireless device 501-a. The adaptive DPD circuit 205-b may be configured to perform the operations described above with reference to FIG. 5. The power amplifier 210-b may take a signal processed by the adaptive DPD circuit 205-b and amplify the power of the signal. The power amplification response of the DPD and the power amplifier 210-b may be linear or non-linear with respect to the input signal based on the mode selected by the adaptive DPD circuit 205-b. The transmitter 510-a may transmit the one or more signals received from other components of the wireless device 501-a.

The transmission parameter identifier 605 may be configured to identify a transmission parameter for a signal to be transmitted by a wireless modem. For example, the transmission parameter may be a data rate or a transmission power.

The mode selector 610 may be configured to select, based at least in part on the data rate of the signal or the transmission power of the signal, one from the group consisting of a first power amplification response or a second power amplification response for the wireless modem (i.e., for the output of the power amplifier 210-b with respect to the input of the adaptive DPD circuit 205-b), wherein the second power amplification response is more linear than the first power amplification response.

The DPD compensation circuit 615 may be configured to compensate a signal prior to power amplification to achieve a desired power amplification response. In some examples, the selecting on of the first power amplification response or the second power amplification response comprises adjusting a DPD circuit of the wireless modem. In some examples, the adjusting the DPD circuit of the wireless modem comprises selecting a pre-distortion function based on the selected power amplification response. The DPD compensation circuit 615 may base the signal compensation on an inverse model the gain and phase characteristics of the power amplifier 210-b so that after the signal is amplified the resulting signal has the desired characteristics.

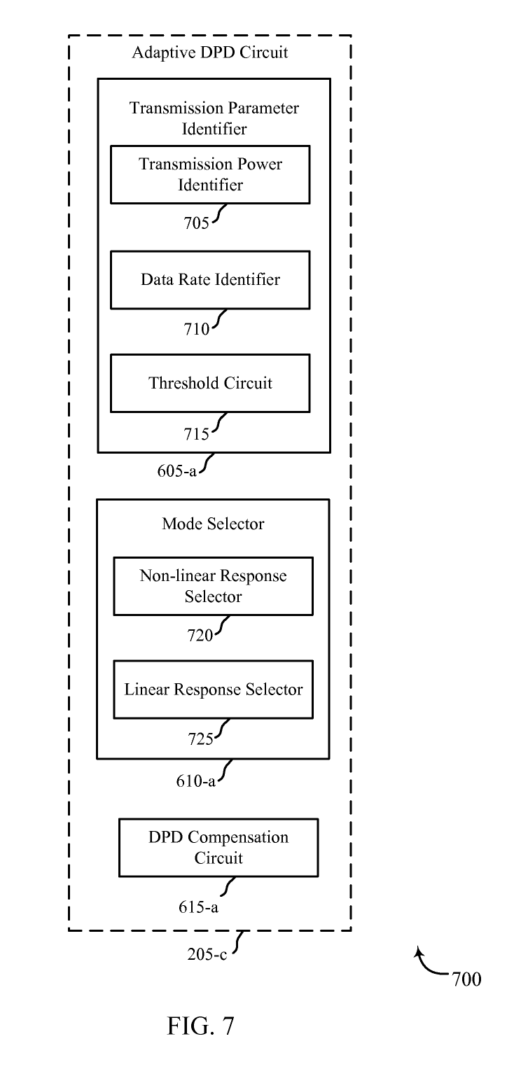

FIG. 7 shows a block diagram 700 of an adaptive DPD circuit 205-c for adaptive digital pre-distortion in accordance with various examples. The DPD circuit 205-c of FIG. 7 may be a component of one from the group consisting of the wireless stations 115 or access point 105 shown in FIG. 1, the wireless devices described with reference to FIGS. 2-4, or the wireless devices 501 shown and described in FIGS. 5-6. The adaptive DPD circuit 205-c may be an example of one or more aspects of an adaptive DPD circuit 205 described with reference to FIGS. 5-6. The adaptive DPD circuit 205-c may include a transmission parameter identifier 605-a, a mode selector 610-a, and a DPD compensation circuit 615-a. Each of these components may perform the functions described above with reference to FIG. 6. The adaptive DPD circuit 205-c may also include a transmission power identifier 705, a data rate identifier 710, a threshold circuit 715, a non-linear response selector 720, and a linear response selector 725.

The components of the adaptive DPD circuit 205-c may, individually or collectively, be implemented with one or more application-specific integrated circuits (ASICs) adapted to perform some or all of the applicable functions in hardware. Alternatively, the functions may be performed by one or more other processing units (or cores), on one or more integrated circuits. In other examples, other types of integrated circuits may be used (e.g., Structured/Platform ASICs, Field Programmable Gate Arrays (FPGAs), and other Semi-Custom ICs), which may be programmed in any manner known in the art. The functions of each unit may also be implemented, in whole or in part, with instructions embodied in a memory, formatted to be executed by one or more general or application-specific processors.

The transmission parameter identifier 605-a may be configured to identify a transmission parameter for a signal to be transmitted by a wireless modem. The mode selector 610-a may also be configured to select based at least in part on a transmission parameter of the signal, one from the group consisting of a first power amplification response or a second power amplification response for the wireless modem, wherein the second power amplification response is more linear than the first power amplification response. The DPD compensation circuit 615 may be configured to compensate a signal prior to power amplification to achieve a desired power amplification response. In some examples, selecting one from the group consisting of the first power amplification response or the second power amplification response may comprise adjusting a DPD circuit of the wireless modem. In some examples, adjusting the DPD circuit of the wireless modem comprises selecting a pre-distortion function based on the selected power amplification response.

The transmission power identifier 705 may determine a transmission power of a wireless device 501. The transmission power may then be passed to the threshold circuit 715 to determine whether it meets a threshold limit.

The data rate identifier 710 may determine a data rate of the signal to be transmitted by the wireless modem. The data rate may then be passed to the threshold circuit 715 to determine whether the data rate meets a threshold limit. In some cases the data rate corresponds to a Modulation and Coding Scheme (MCS), which may be identified by an MCS index. In some cases, the threshold may be based on whether a binary phase-shift keying (BPSK), quadrature phase-shift keying (QPSK), 16-QAM (quadrature amplitude modification) or 64-QAM MCS is used. As another example, the threshold may be whether the coding rate is greater than ½.

The threshold circuit 715 may determine whether a transmission parameter such as a transmission power or a data rate meets a threshold limit to determine which adaptive DPD mode to select. For example, a non-linear DPD mode may be selected if the data rate is below a threshold, and a linear DPD mode may be selected if the data rate is above a threshold. In the case that the transmission parameter is a transmission power, the non-linear DPD mode may be selected if the transmission power is above a threshold limit and the linear DPD mode may be selected if the transmission power is below the threshold.

The non-linear response selector 720 may determine a non-linear target output power amplification response as described above with reference to FIG. 4B. The non-linear response selector may then determine. The linear response selector 725 may determine a linear target output power amplification response as described above with reference to FIG. 4A. The power amplification response may then be passed to the DPD compensation circuit 615-a, which may select a pre-amplification distortion necessary to obtain the selected response.

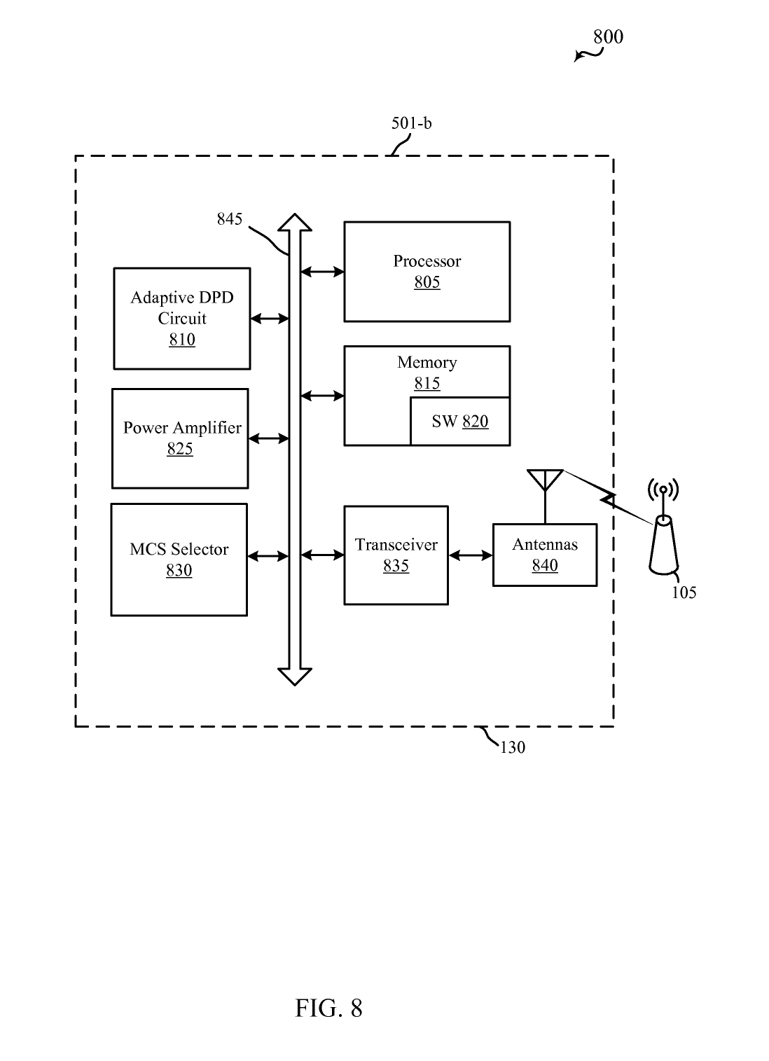

FIG. 8 shows a diagram of a system 800 for adaptive digital pre-distortion in accordance with various examples. The system 800 may include a wireless device 501-b, The wireless device 501-b may be an example of one or more aspects of the wireless stations 115 or access point 105 shown in FIG. 1, the wireless devices described with reference to FIGS. 2-4, or the wireless devices 501 shown and described in FIGS. 5-7. In some cases, the wireless device 501-b may also be an example of an AP 105 with reference to FIG. 1. The wireless device 501-b may generally include components for bi-directional voice and data communications including components for transmitting communications and components for receiving communications. The wireless device 501-b may include an adaptive DPD circuit 810 which may be an example of one of the adaptive DPD circuits 205 shown and described with reference to FIGS. 2 and 5-7.

The wireless device 501-b may include antenna(s) 840, a transceiver 835, a processor 805, and memory 815 (including software (SW)) 820, which each may communicate, directly or indirectly, with each other (e.g., via one or more buses 845. The transceiver 835 may be configured to communicate bi-directionally, via the antenna(s) 840 and/or one or more wired or wireless links, with one or more networks, as described above. For example, the transceiver 835 may be configured to communicate bi-directionally with an AP 105. The transceiver 835 may include a wireless modem configured to modulate the packets and provide the modulated packets to the antenna(s) 840 for transmission, and to demodulate packets received from the antenna(s) 840. While the wireless device 501-b may include a single antenna 840, the wireless device 501-b may also have multiple antennas 840 capable of concurrently transmitting and/or receiving multiple wireless transmissions. The transceiver 835 may also be capable of concurrently communicating with one or more APs 105. In the case where the wireless device 501-b corresponds to an AP 105, the transceiver 835 may also communicate bi-directionally with other wireless stations 115 and access points 105.

The memory 815 may include random access memory (RAM) and read-only memory (ROM). The memory 815 may store computer-readable, computer-executable software/firmware code 820 containing instructions that are configured to, when executed, cause the processor 805 to perform various functions described herein (e.g., call processing, database management, processing of carrier mode indicators, reporting CSI, etc.). Alternatively, the computer-executable software/firmware code 820 may not be directly executable by the processor 805 but be configured to cause a computer (e.g., when compiled and executed) to perform functions described herein. The processor 805 may include an intelligent hardware device, e.g., a central processing unit (CPU), a microcontroller, an application-specific integrated circuit (ASIC), etc. may include random access memory (RAM) and read-only memory (ROM). The memory 815 may store computer-readable, computer-executable software/firmware code 820 containing instructions that are configured to, when executed, cause the processor 805 to perform various functions described herein (e.g., call processing, database management, processing of carrier mode indicators, reporting CSI, etc.). Alternatively, the computer-executable software/firmware code 820 may not be directly executable by the processor 805 but be configured to cause a computer (e.g., when compiled and executed) to perform functions described herein. The processor 805 may include an intelligent hardware device, e.g., a central processing unit (CPU), a microcontroller, an application-specific integrated circuit (ASIC), etc.

The MCS selector 830 may be configured to select an MCS for a signal to be transmitted. In some examples, the transmission parameter that may serve as the basis for selecting a DPD mode may correspond to the selected MCS. In some cases, The MCS may be associated with an MCS index.

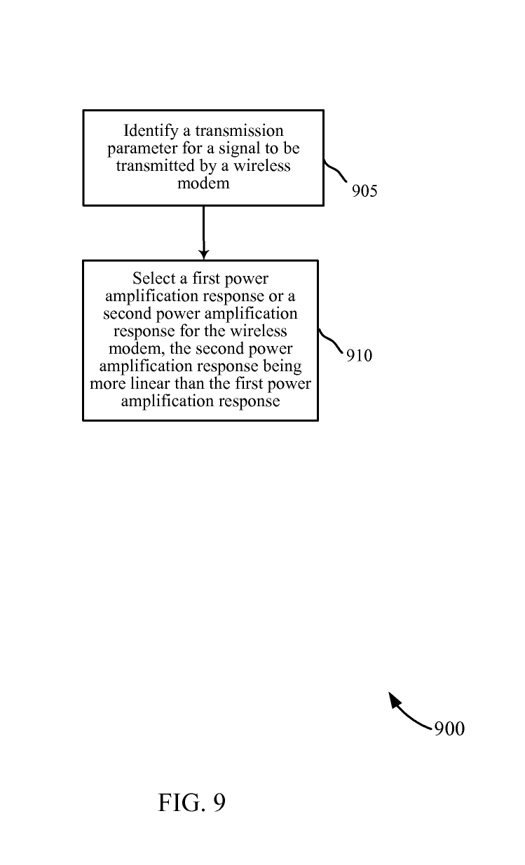

FIG. 9 shows a flowchart 900 illustrating a method for adaptive digital pre-distortion in accordance with various examples. The functions of flowchart 900 may be implemented by one of the wireless stations 115 or access point 105 shown in FIG. 1, the wireless devices described with reference to FIGS. 2-4, or the wireless devices 501 shown and described in FIGS. 5-7. In certain examples, the blocks of the flowchart 900 may be performed by one of the adaptive DPD circuits 205 shown and described with reference to FIGS. 2 and 5-8.

At block 905, the wireless device 501 may identify a transmission parameter for a signal to be transmitted by a wireless modem. The transmission parameter may be a transmission power or a data rate. In certain examples, the functions of block 905 may be performed by the transmission parameter identifier 605 as described above with reference to FIGS. 6-7.

At block 910, the wireless device 501 may select, based at least in part on a data rate or a transmission power of the signal, one from the group consisting of a first power amplification response or a second power amplification response for the wireless modem, wherein the second power amplification response is more linear than the first power amplification response. In certain examples, the functions of block 910 may be performed by the mode selector 610 as described above with reference to FIGS. 6-7.

It should be noted that the method of flowchart 900 is just one implementation and that the operations of the method, and the steps may be rearranged or otherwise modified such that other implementations are possible.

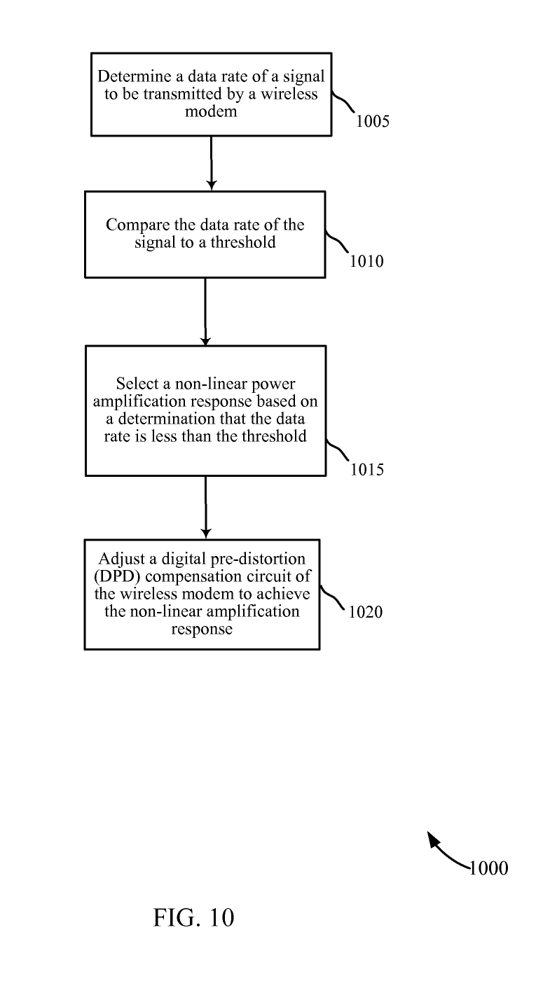

FIG. 10 shows a flowchart 1000 illustrating a method for adaptive digital pre-distortion in accordance with various examples. The functions of flowchart 1000 may be implemented by one of the wireless stations 115 or access point 105 shown in FIG. 1, the wireless devices described with reference to FIGS. 2-4, or the wireless devices 501 shown and described in FIGS. 5-7. In certain examples, the blocks of the flowchart 1000 may be performed by one of the adaptive DPD circuits 205 shown and described with reference to FIGS. 2 and 5-8. The method described in flowchart 1000 may also incorporate aspects of flowchart 900 of FIG. 9.

At block 1005, the wireless device 501 may determine a data rate for a signal to be transmitted by a wireless modem. The data rate may correspond to an MCS or an MCS index. In certain examples, the functions of block 1005 may be performed by the data rate identifier 710 as described above with reference to FIG. 7.

At block 1010, the wireless device 501 may compare the data rate of the signal to a threshold. In certain examples, the functions of block 1010 may be performed by the threshold circuit 715 as described above with reference to FIG. 7.

At block 1015, the wireless device 501 may select a first power amplification response in response to a determination that the data rate is less than the threshold. The first power amplification response may be a non-linear power amplification response as described above with reference to FIG. 4B. In certain examples, the functions of block 1015 may be performed by the threshold circuit 715 as described above with reference to FIG. 8.

At block 1020, the wireless device 501 may adjust a DPD circuit of the wireless modem. For example, it may coordinate with a DPD compensation circuit 615 to apply a distorting compensation prior to power amplification to achieve the non-linear power amplification response. In certain examples, the functions of block 1020 may be performed by the threshold circuit 715 as described above with reference to FIG. 8.

It should be noted that the method of flowchart 1000 is just one implementation and that the operations of the method, and the steps may be rearranged or otherwise modified such that other implementations are possible.

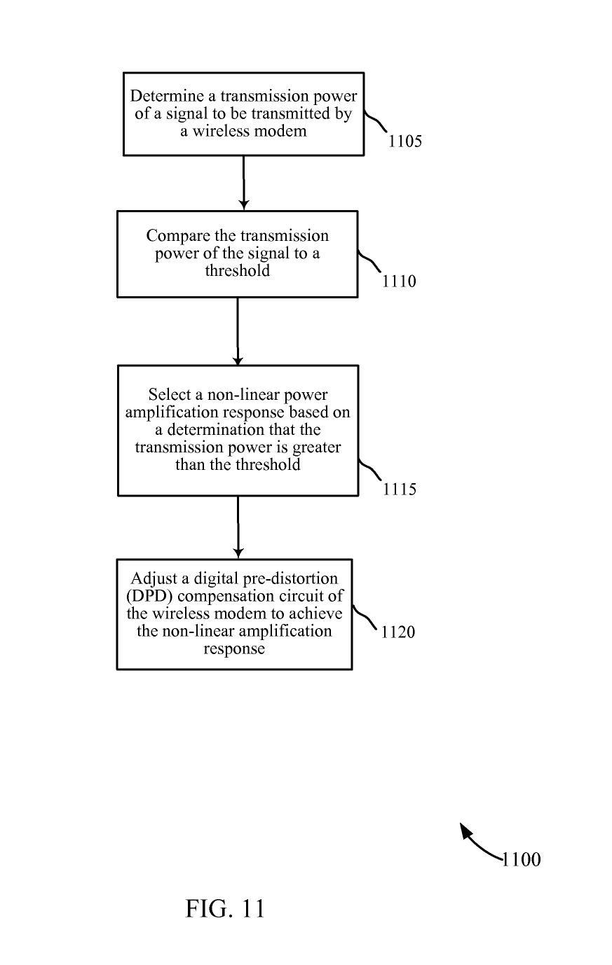

FIG. 11 shows a flowchart 1100 illustrating a method for adaptive digital pre-distortion in accordance with various examples. The functions of flowchart 1100 may be implemented by a wireless device 501 or its components as described with reference to FIGS. 1-8 In certain examples, the blocks of the flowchart 1000 may be performed by one of the adaptive DPD circuits 205 shown and described with reference to FIGS. 2 and 5-8. The method described in flowchart 1100 may also incorporate aspects of flowcharts 900 of FIG. 9.

At block 1105, the wireless device 501 may determine a transmission power for a signal to be transmitted by a wireless modem. In certain examples, the functions of block 1025 may be performed by the transmission power identifier 705 as described above with reference to FIG. 8.

At block 1110, the wireless device 501 may compare the transmission power of the signal to a threshold. In certain examples, the functions of block 1030 may be performed by the threshold circuit 715 as described above with reference to FIG. 8.

At block 1115, the wireless device 501 may select a first power amplification response in response to a determination that the transmission power is less than the threshold. The first power amplification response may be a non-linear power amplification response as described above with reference to FIG. 4B. In certain examples, the functions of block 1015 may be performed by the threshold circuit 715 as described above with reference to FIG. 8.

At block 1120, the wireless device 501 may adjust a DPD circuit of the wireless modem. For example, it may coordinate with a DPD compensation circuit 615 to apply a distorting compensation prior to power amplification to achieve the non-linear power amplification response. In certain examples, the functions of block 1020 may be performed by the threshold circuit 715 as described above with reference to FIG. 8.

It should be noted that the method of flowchart 1100 is just one implementation and that the operations of the method, and the steps may be rearranged or otherwise modified such that other implementations are possible.

The detailed description set forth above in connection with the appended drawings describes examples and does not represent the only examples that may be implemented or that are within the scope of the claims. The term “exemplary” used throughout this description means “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and devices are shown in block diagram form in order to avoid obscuring the concepts of the described examples.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various illustrative blocks and components described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described above can be implemented using software executed by a processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items (for example, a list of items prefaced by a phrase such as “at least one of” or “one or more of”) indicates a disjunctive list such that, for example, a list of [at least one of A, B, or C] means A or B or C or AB or AC or BC or ABC (i.e., A and B and C).

Computer-readable media includes both computer storage media and communication media including any medium that facilitates transfer of a computer program from one place to another. A storage medium may be any available medium that can be accessed by a general purpose or special purpose computer. By way of example, and not limitation, computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The previous description of the disclosure is provided to enable a person skilled in the art to make or use the disclosure. Various modifications to the disclosure will be readily apparent to those skilled in the art, and the generic principles defined herein may be applied to other variations without departing from the scope of the disclosure. Throughout this disclosure the term “example” or “exemplary” indicates an example or instance and does not imply or require any preference for the noted example. Thus, the disclosure is not to be limited to the examples and designs described herein but is to be accorded the widest scope consistent with the principles and novel features disclosed herein.

What is claimed is:

1. A method of adaptive digital pre-distortion (DPD), comprising:
identifying a transmission parameter for a signal to be transmitted by a wireless modem, wherein the transmission parameter is selected from the group consisting of:
a transmission power and a data rate; and
selecting, based at least in part on the transmission parameter of the signal, one from the group consisting of a first power amplification response or a second power amplification response for the wireless modem, wherein the second power amplification response is more linear than the first power amplification response.

2. The method of claim 1, further comprising:
comparing the transmission parameter of the signal to a threshold.

3. The method of claim 2, wherein selecting one from the group consisting of the first power amplification response or the second power amplification response comprises:
selecting the first power amplification response in response to a determination that the data rate is less than the threshold.

4. The method of claim 2, wherein selecting one from the group consisting of the first power amplification response or the second power amplification response comprises:
selecting the second power amplification response in response to a determination that the data rate is greater than the threshold.

5. The method of claim 2, wherein selecting one from the group consisting of the first power amplification response or the second power amplification response comprises:
selecting the first power amplification response in response to a determination that the transmission power is greater than the threshold.

6. The method of claim 2, wherein selecting one from the group consisting of the first power amplification response or the second power amplification response comprises:
selecting the second power amplification response in response to a determination that the transmission power is less than the threshold.

7. The method of claim 1, wherein the data rate corresponds to a modulation and coding scheme (MCS) index.

8. The method of claim 1, wherein selecting one from the group consisting of the first power amplification response or the second power amplification response comprises:
adjusting a DPD compensation circuit of the wireless modem.

9. The method of claim 8, wherein adjusting the DPD compensation circuit of the wireless modem comprises:
selecting a pre-distortion function based on the selected power amplification response.

10. The method of claim 1, wherein the first power amplification response is characterized by a non-linear Rapp function.

11. The method of claim 1, wherein the second power amplification response is characterized by a piecewise linear function.

12. An apparatus for adaptive digital pre-distortion (DPD), comprising:
means for identifying a transmission parameter for a signal to be transmitted by a wireless modem, wherein the transmission parameter is selected from the group consisting of: a transmission power and a data rate; and
means for selecting, based at least in part on the transmission parameter of the signal, one from the group consisting of a first power amplification response or a second power amplification response for the wireless modem, wherein the second power amplification response is more linear than the first power amplification response.

13. The apparatus of claim 12, further comprising:
means for comparing the transmission parameter of the signal to a threshold.

14. The apparatus of claim 13, wherein the means for selecting one from the group consisting of the first power amplification response or the second power amplification response comprises:
means for selecting the first power amplification response in response to a determination that the data rate is less than the threshold.

15. The apparatus of claim 13, wherein the means for selecting one from the group consisting of the first power amplification response or the second power amplification response comprises:
means for selecting the first power amplification response in response to a determination that the transmission power is greater than the threshold.

16. The apparatus of claim 12, wherein the data rate corresponds to an MCS index.

17. The apparatus of claim 12, wherein the means for selecting one from the group consisting of the first power amplification response or the second power amplification response comprises:
means for adjusting a DPD compensation circuit of the wireless modem.

18. The apparatus of claim 17, wherein the means for adjusting the DPD compensation circuit of the wireless modem comprises:
means for selecting a pre-distortion function based on the selected power amplification response.

19. The apparatus of claim 12, wherein the first power amplification response is characterized by a non-linear Rapp function.

20. The apparatus of claim 12, wherein the second power amplification response is characterized by a piecewise linear function.

21. An apparatus for adaptive digital pre-distortion (DPD), comprising an adaptive DPD circuit and a power amplifier, wherein the adaptive DPD circuit is configured to:
identify a transmission parameter for a signal to be transmitted by a wireless modem, wherein the transmission parameter is selected from the group consisting of: a transmission power and a data rate; and
select based at least in part on the transmission parameter of the signal, one from the group consisting of a first power amplification response or a second power amplification response for the wireless modem, wherein the second power amplification response is more linear than the first power amplification response.

22. The apparatus of claim 21, wherein the adaptive DPD circuit is further configured to:
compare the transmission parameter of the signal to a threshold.

23. The apparatus of claim 22, wherein selecting one from the group consisting of the first power amplification response or the second power amplification response comprises:
selecting the first power amplification response in response to a determination that the data rate is less than the threshold.

24. The apparatus of claim 22, wherein selecting one from the group consisting of the first power amplification response or the second power amplification response comprises:
selecting the first power amplification response in response to a determination that the transmission power is greater than the threshold.

25. The apparatus of claim 21, wherein the data rate corresponds to an MCS index.

26. The apparatus of claim 21, wherein selecting one from the group consisting of the first power amplification response or the second power amplification response comprises:
adjusting a DPD compensation circuit of the wireless modem.

27. The apparatus of claim 26, wherein adjusting the DPD compensation circuit of the wireless modem comprises:
selecting a pre-distortion function based on the selected power amplification response.

28. The apparatus of claim 21, wherein the first power amplification response is characterized by a non-linear Rapp function.

29. The apparatus of claim 21, wherein the second power amplification response is characterized by a piecewise linear function.

30. A computer program product for adaptive digital pre-distortion (DPD), the computer program product comprising a non-transitory computer-readable medium storing instructions executable by a processor to:
identify a transmission parameter for a signal to be transmitted by a wireless modem, wherein the transmission parameter is selected from the group consisting of: a transmission power and a data rate; and
select based at least in part on the transmission parameter of the signal, one from the group consisting of a first power amplification response or a second power amplification response for the wireless modem, wherein the second power amplification response is more linear than the first power amplification response.
